(19) United States
(12) Patent Application Publication
(10) Pub. No.: US 2024/0347939 A1
(43) Pub. Date: Oct. 17, 2024

(54) Electronic Assembly

(71) Applicants: TE Connectivity Solutions GmbH, Schaffhausen (CH); Tyco Electronics (Shanghai) Co., Ltd., Shanghai (CN)

(72) Inventors: Wei (David) Zhao, Shanghai (CN); Joshua Tyler Sechrist, Tigard, OR (US); Christopher Blackburn, Bothell, WA (US)

(73) Assignees: TE Connectivity Solutions GmbH, Schaffhausen (CH); Tyco Electronics (Shanghai) Co., Ltd., Shanghai (CN)

(21) Appl. No.: 18/632,884

(22) Filed: Apr. 11, 2024

(30) Foreign Application Priority Data
Apr. 14, 2023 (CN) 202310403198.7

(51) Int. Cl. H01R 12/71; H05K 1/18; H05K 3/34

(52) U.S. Cl. CPC H01R 12/714; H05K 1/181; H05K 3/3436; H05K 2201/10265; H05K 2201/1053; H05K 2201/10598

(57) ABSTRACT

An electronic assembly comprises a circuit board, a connector module, and a fixing assembly. The connector module includes a module housing and connection members at least partially accommodated therein. An engagement structure is formed on the module housing. The fixing assembly is adapted to be engaged with the engagement structure to secure the connector module to the circuit board, such that the connection members are electrically connected to the circuit board.

### CROSS-REFERENCE TO RELATED APPLICATION

This application claims the priority of Chinese Patent Application No. CN 202310403198.7 filed on Apr. 14, 2023, the whole disclosure of which is incorporated herein by reference.

### FIELD OF THE INVENTION

The present disclosure relates to an electronic assembly.

### BACKGROUND

A pressure-exerting device is usually used to firmly press a connector module onto a circuit board in an electronic assembly. A conventional pressure-exerting device usually includes an additional pressing plate, a spring for applying a pressure to the pressing plate, and a screw for positioning the spring. As a result of this construction, the electronic assembly takes up a larger space or volume. In addition, a shell of the electronic assembly for protecting the connector module is usually fixed to the circuit board by inserting pins into holes of the circuit board. Therefore, a large number of holes are formed in the circuit board, which in turn affects the layout of leads or traces in the circuit board. In addition, there is a typically a large gap between the shell and the connector module, making the connector module prone to tilt when it is pre-installed onto the circuit board. In the electronic assembly where a socket connector is present between the circuit board and the connector module, a position of a protrusion for positioning and fixing the socket connector on a shell wall of the shell is fixed, making it extremely difficult to remove the socket connector from the circuit board or the shell.

### SUMMARY

According to one embodiment of the present disclosure, an electronic assembly comprises a circuit board, a connector module, and a fixing assembly. The connector module includes a module housing and connection members at least partially accommodated therein. An engagement structure is formed on the module housing. The fixing assembly is adapted to be engaged with the engagement structure to secure the connector module to the circuit board, so that the connection members are electrically connected to the circuit board.

### BRIEF DESCRIPTION OF THE DRAWINGS

The invention will now be described by way of example with reference to the accompanying Figures, of which:

FIG. 1 shows a perspective view of an electronic assembly after being assembled according to the present disclosure.

FIG. 2 shows an exploded perspective view of an electronic assembly according to the present disclosure.

FIG. 3 shows an exploded perspective view of a connector module of an electronic assembly according to the present disclosure.

FIG. 4 shows an assembly view of an electronic assembly according to the present disclosure.

FIG. 5 shows a perspective view of a shell of an electronic assembly according to the present disclosure.

FIG. 6 shows a perspective view of a socket connector of an electronic assembly according to the present disclosure.

FIG. 7 shows a cross-sectional view of the electronic assembly shown in FIG. 1.

FIG. 8 shows a partially enlarged view of the cross-sectional view of the electronic assembly shown in FIG. 7.

The features disclosed in this disclosure will become more apparent in the following detailed description in conjunction with the accompanying drawings, where similar reference numerals always identify the corresponding components. In the accompanying drawings, similar reference numerals typically represent identical, functionally similar, and/or structurally similar components. Unless otherwise stated, the drawings provided throughout the entire disclosure should not be construed as drawings drawn to scale.

### DETAILED DESCRIPTION OF THE EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

An embodiment of the present disclosure provides an electronic assembly including a circuit board 200, a connector module 100 and a fixing assembly. The connector module 100 has a module housing 120 and connection members 110 at least partially accommodated within the module housing. An engagement structure is formed on the module housing 120. The fixing assembly is adapted to engaged with the engagement structure to secure the connector module 100 to the circuit board 200 such that the connection members 110 are electrically connected to the circuit board.

In some embodiments, as better shown in FIG. 2, the electronic assembly further includes a shell 300 and a socket connector 400. The shell 300 is adapted to surround the connector module 100. The socket connector 400 is adapted to be placed inside the shell 300, and the connector module 100 is electrically connected to the circuit board 200 via the socket connector 400.

In various embodiments of the present disclosure, the connector module 100 may include an optical connector module and an electrical connector module, where the optical connector module may have an optical fiber led out from the connection member 110, and the electrical connector module may have an electrical cable led out from the connection member 110.

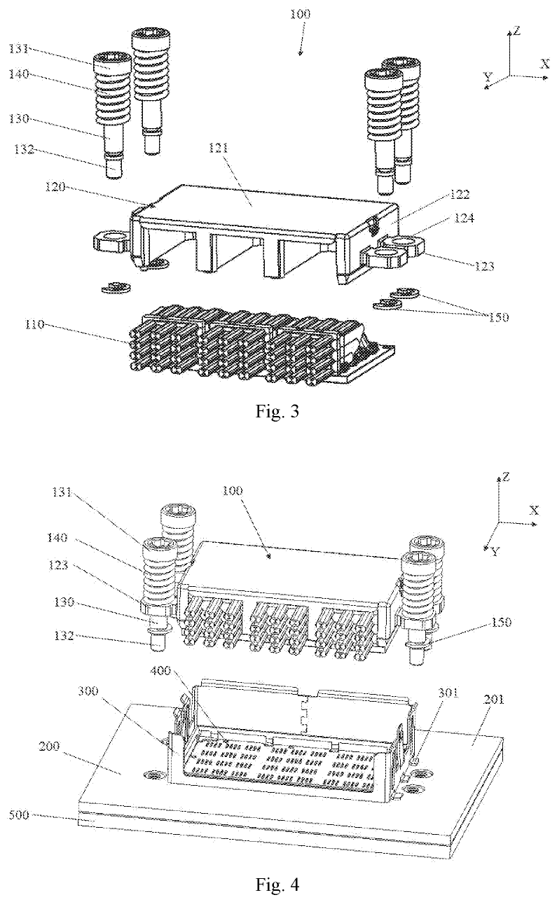

The module housing 120 for accommodating and protecting the connection members 110 is a portion of the connector module 100, and is typically made of an insulating material such as insulating plastic. As better shown in FIG. 3, the module housing 120 has a top wall 121 and side walls 122 extending from the top wall 121 in a direction towards the circuit board 200. A space for accommodating and protecting the connection members 110 is defined by the top wall 121 and the side walls 122. The module housing 120 may have at least two side walls 122 located on opposite sides of the top wall 121 in a first direction X. In addition, the module housing 120 may further include between the two opposite side walls 122 one or more additional side walls extending from the top wall 121 in a direction perpendicular to the top wall 121, and the additional side walls may separate the connection members 110 from each other.

As shown in FIG. 3, the engagement structure may be a portion of the module housing 120 made of the insulating material, and includes a shoulder 123 protruding laterally from the module housing 120, a through-hole 124 being formed in the shoulder 123. The shoulder 123 extends outwardly in the form of a cantilever from an outer side surface of the side wall 122 of the module housing 120, and a top surface of the shoulder 123 is lower than a top surface of the top wall 121 of the module housing 120.

At least one shoulder 123 is formed on the outer side surface of each side wall 122. In some embodiments, as better shown in FIG. 4, there are two shoulders 123 at two ends of one of the two opposite side walls 122 in a second direction Y. There are two shoulders 123 in the middle of the other one of the two side walls 122 in the second direction Y.

In some embodiments provided by the present disclosure, the fixing assembly includes a fastener 130, such as a bolt and a stud. The fastener 130 is adapted to pass through the through-hole 124 in the shoulder 123 of the module housing 120 and to be connected to the circuit board 200, thereby fixing the connector module 100 relative to the circuit board. Thus, because the top surface of the shoulder 123 protruding from the side wall 122 of the module housing 120 in the form of the cantilever is lower than that of the top wall 121 of the module housing 120, a height of the fastener 130 protruding beyond the top surface of the module housing may be reduced.

The electronic assembly of the present disclosure is provided with the shoulder formed on the housing of a conventional connector module, thereby omitting a pressing plate of a pressure-exerting device of a conventional electronic assembly and minimizing a top space occupied by the electronic assembly. The shoulder has a height lower than that of the top wall of the module housing of the connector module, so that the space occupied by the connector module is further reduced.

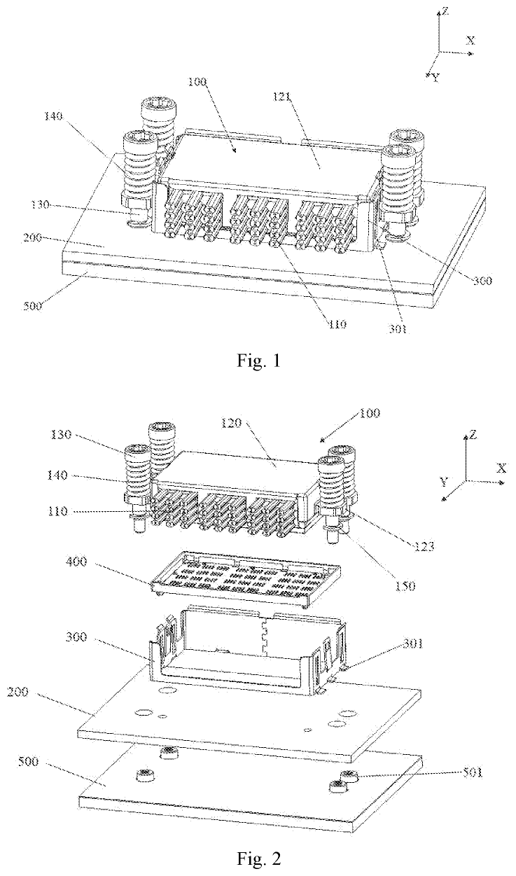

In addition, as shown in FIGS. 1-4, in some embodiments, the fixing assembly may further include a spring 140 adapted to be axially sleeved over the fastener 130. A head 131 of the fastener has a larger diameter than that of a longitudinal body of the fastener, so that the spring 140 is adapted to be compressed between the head 131 of the fastener and the shoulder 123 of the module housing 120 to generate an elastic force. The elastic force provides a pressure downwardly to press the connector module 100 towards the circuit board 200. Thus, the connector module 100 is firmly installed with the circuit board 200.

In some embodiments, a socket connector 400 may be provided between the connector module 100 and the circuit board 200, as shown in FIG. 6. The socket connector 400 may include clastic conductors 410. A plurality of elastic conductors 410 may be arranged on the socket connector 400 in the form of an array with a plurality of rows and a plurality of columns. Thus, the connection members 110 of the connector module 100 may establish electrical connections with the circuit board 200 via the elastic conductors 410 of the socket connector 400. In this case, the elastic force generated by the spring 140 compressed between the head 131 of the fastener and the shoulder 123 of the module housing 120 may compress the socket connector 400 located between the connector module 100 and the circuit board 200, thereby establishing the stable electrical connection.

As better shown in FIGS. 3 and 4, in some embodiments, the fixing assembly may further include a stopper 150 adapted to be detachably installed to the longitudinal body of the fastener 130. This prevents the fastener 130 and the spring 140 from falling off from the connector module 100 after being assembled with the connector module. In some embodiments, the spring 140 may be fixed with the head 131 of the fastener, such as by welding or by bonding via adhesive, thereby preventing the spring 140 from falling off from the fastener 130.

As better shown in FIGS. 1-4 and 7, in some embodiments, the fixing assembly may further include a back plate 500. The back plate 500 is located on a side of the circuit board 200 opposite to the connector module 100. The fastener 130 is adapted to be detachably connected to the back plate 500 through the through-hole 124 of the shoulder 123 and a corresponding installation hole in the circuit board 200.

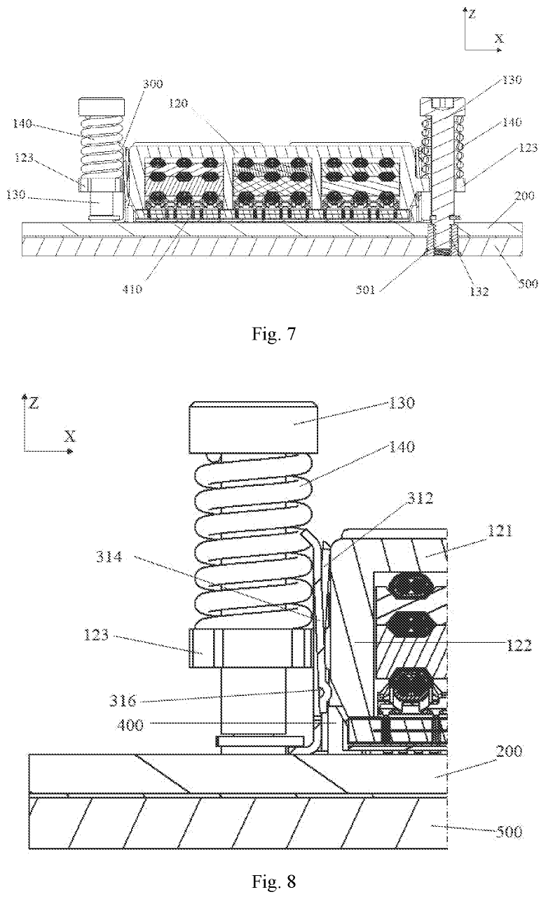

In addition, as better shown in FIGS. 2 and 7, the fixing assembly may further include a nut 501 located on a side of the back plate 500 opposite to the circuit board 200. The other end of the fastener 130 opposite to its head 131 has a threaded portion 132. The fastener 130 is connected to the back plate 500 by the engagement of the threaded portion 132 and the nut 501. In addition, an engagement length between the threaded portion 132 and the nut 501 is adjustable, and thus the elastic force of the spring 140 between the head 131 of the fastener 130 and the shoulder 123 may be adjusted.

In some embodiments of the present disclosure, the electronic assembly further includes a shell 300 in the form of a frame. The shell 300 is adapted to be fixed on the circuit board 200 around a periphery of the connector module 100, thereby limiting the displacement of the connector module 100 relative to the circuit board 200 in a plane parallel to a surface 201 of the circuit board. In the case where the socket connector 400 is provided between the connector module 100 and the circuit board 200, the shell 300 may further limit the displacement of the socket connector 400 relative to the circuit board 200 in the plane parallel to the surface 201 of the circuit board.

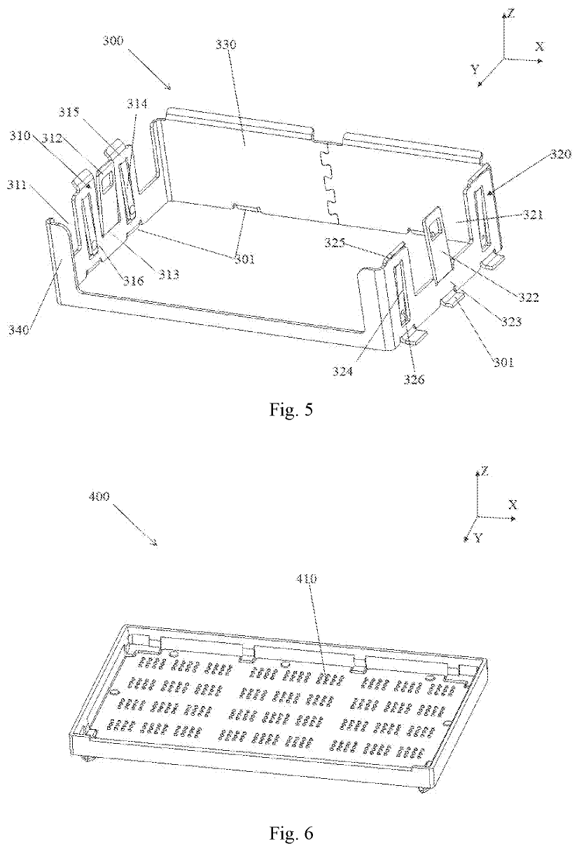

As better shown in FIGS. 4 and 5, the shell 300 is formed with solder pads 301 adapted to be soldered to the surface 201 of the circuit board 200. Because the shell of electronic assembly is fixed to the circuit board by the solder pad, the formation of holes in the circuit board, which would affect the layout of leads or traces, is not required.

The shell 300 may include a first shell wall 310 and a second shell wall 320 located opposite to each other in a first direction X, and a third shell wall 330 and a fourth shell wall 340 connecting the first shell wall 310 and the second shell wall 320. The solder pads 301 may be formed at a base of each of the first shell wall 310, the second shell wall 320, and the third shell wall 330. A notch may be formed in the fourth shell wall 340, as shown in FIG. 1. The connection members 110 of the connector module 100 may be lead out through the notch of the fourth shell wall 340.

In various embodiments provided by the present disclosure, the first shell wall 310 and the second shell wall 320 are adapted to be at least partially butted against the side walls 122 of the module housing 120 to limit the displacement of the connector module 100 in the first direction X. In the case where the socket connector 400 is provided between the connector module 100 and the circuit board 200, the first shell wall 310 and the second shell wall 320 may limit the displacement of the socket connector 400 in the first direction X.

As better shown in FIG. 1, each of the first shell wall 310 and the second shell wall 320 are adapted to be respectively positioned between one of the side walls 122 of the module housing 120 and the fastener 130 of the fixing assembly. As shown in FIG. 5, notches 311, 321 adapted to be passed through by the shoulders 123 of the module housing 120 are formed in the first shell wall 310 and the second shell wall 320, respectively.

As better shown in FIG. 5, at least one elastic arm is formed on at least one of the first shell wall 310 and the second shell wall 320, preferably the two shell walls 310 and 320. The at least one elastic arm is adapted to be at least partially elastically butted against the side walls 122 of the module housing when the connector module 100 is positioned inside the shell 300. The at least one elastic arm includes at least one of the first elastic arm 312, 322 and the second elastic arm 314, 324. As shown in FIG. 5, the first elastic arm 312 or 322 extends from a base 313 or 323 of the corresponding shell wall 310 or 320 in a direction away from the circuit board 200 and is inclined towards inside of the shell 300. As shown in FIGS. 7 and 8, at least a free end of the first elastic arm 312 or 322 can be elastically butted against the side wall 122 of the module housing. As shown in FIG. 5, the second clastic arm 314 or 324 extends from a top 315 or 325 of the corresponding shell wall 310 or 320 in a direction towards the circuit board 200 and is inclined towards inside of the shell 300. In some embodiments, at least a portion of the second elastic arm 314 or 324 can be elastically butted against the side wall 122 of the module housing. Thus, the shell is butted against the side walls of the connector module via the first and/or second elastic arms to prevent the connector module from tilting during the pre-assembly process.

In some embodiments provided by the present disclosure where the socket connector 400 is provided between the connector module 100 and the circuit board 200, as shown in FIGS. 7 and 8, the free ends of the second elastic arms 314, 324 are adapted to press against the socket connector 400 in a direction towards the connector module 100. As shown in FIG. 5, protrusions 316, 326 may be formed on inner surfaces of the free ends of the second clastic arms 314, 324 facing the connector module 100. As shown in FIGS. 7 and 8, the protrusions 316, 326 are adapted to press an upper edge of the socket connector 400 in a direction towards the circuit board 200, thereby positioning the socket connector 400.

Thus, the protrusion for positioning and fixing the socket connector is formed on the second elastic arm of the shell wall, making it easy to disassemble the socket connector located between the circuit board and the connector module by the floating of the second elastic arm. In some embodiments of the present disclosure, the at least one elastic arm of each of the first shell wall 310 and the second shell wall 320 includes two second elastic arms 314, 324. One first elastic arm 312, 322 is located between the two second elastic arms 314, 324.

As better shown in FIG. 5, the first shell wall 310 may include two second elastic arms 314 and one first clastic arm 312 located between the two second elastic arms 314. The first shell wall 310 may include two first notches 311. The one first elastic arm 312 and the two second elastic arms 314 of the first shell wall 310 are provided between the two first notches 311.

In addition, the second shell wall 320 may include two second clastic arms 324 and one first elastic arm 322 located between the two second elastic arms 324. The second shell wall 320 may include two second notches 321. Each of the second notches is provided between the first clastic arm 322 and the second elastic arm 324 of the second shell wall 320.

In various embodiments provided by the present disclosure, the shell 300 is integrally formed by stamping and bending a single metal plate. Correspondingly, the various features of the shell 300 are also integrally formed by stamping and bending the single metal plate. Two ends of the above-mentioned metal plate are formed with a protrusion and a recess, which are complementary and can be embedded and connected with each other to form the third shell wall 330 of the shell 300, as better shown in FIG. 5. Thus, the shell has a lower manufacturing cost.

The electronic assembly provided by the various embodiments of the present disclosure is provided with a shoulder integrally formed on the housing of the connector module, thereby omitting the pressing plates of the pressure-exerting devices of the conventional electronic assemblies and reducing the top space occupied by the electronic assembly. In addition, the shoulder has a height lower than that of a top wall of the module housing, further reducing the occupied space. Further, the shell of the electronic assembly provided by the present application is fixed to the circuit board by the solder pads, thereby avoiding the holes formed in the circuit board which would affect the layout of leads or traces. The shell is butted against the side walls of the connector module by the elastic arms to prevent tilting during the pre-assembly process. Additionally, the protrusion for positioning and fixing the socket connector are formed on the elastic arm of the shell, making it easy to disassemble the socket connector located between the circuit board and the connector module by the floating of the elastic arm.

In addition, those areas in which it is believed that those of ordinary skill in the art are familiar, have not been described herein in order not to unnecessarily obscure the invention described. Accordingly, it has to be understood that the invention is not to be limited by the specific illustrative embodiments, but only by the scope of the appended claims.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of the elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. An electronic assembly, comprising:
a circuit board;
a connector module having a module housing and connection members at least partially accommodated within the module housing, the module housing including an engagement structure formed thereon; and
a fixing assembly adapted to be engaged with the engagement structure to secure the connector module to the circuit board including the connection members electrically connected to the circuit board.

2. The electronic assembly according to claim 1, further comprising a shell and a socket connector, wherein:
the shell surrounds the connector module;
the socket connector is arranged inside the shell; and
the connector module is electrically connected to the circuit board via the socket connector.

3. The electronic assembly according to claim 1, wherein:
the engagement structure includes a shoulder protruding laterally from the module housing and having a through-hole formed therein; and
the fixing assembly includes a fastener adapted to pass through the through-hole in the shoulder and to be connected with the circuit board to fix the connector module relative to the circuit board.

4. The electronic assembly according to claim 3, wherein:
the module housing has a top wall and side walls extending from the top wall in a direction towards the circuit board, a space for accommodating the connection members is defined by the top wall and the side walls; and
the shoulder extends outwardly in the form of a cantilever from an outer side surface of the side wall, wherein a top surface of the shoulder is lower than that of the top wall.

5. The electronic assembly according to claim 4, wherein the module housing has at least two side walls located on opposite sides of the top wall in a first direction, and at least one shoulder is formed on the outer side surface of each of the side walls.

6. The electronic assembly according to claim 3, wherein the fixing assembly further includes a spring adapted to be axially sleeved over the fastener, and the spring is adapted to be compressed between a head of the fastener and the shoulder to generate an elastic force downwardly pressing the connector module towards the circuit board.

7. The electronic assembly according to claim 6, wherein the fixing assembly further includes a stopper adapted to be detachably connected to the fastener, the stopper adapted to prevent the fastener and the spring from separating from the connector module after being assembled therewith.

8. The electronic assembly according to claim 3, wherein the fixing assembly further includes a back plate located on a side of the circuit board opposite to the connector module, and the fastener is adapted to be detachably connected to the back plate through the through-hole in the shoulder and a corresponding installation hole in the circuit board.

9. The electronic assembly according to claim 8, wherein the fixing assembly further includes a nut located on a side of the back plate opposite to the circuit board, an end of the fastener opposite to its head has a threaded portion, and the fastener is connected to the back plate via engagement of the threaded portion and the nut.

10. The electronic assembly according to claim 9, wherein an engagement length between the threaded portion and the nut is adjustable to alter an elastic force of a spring between the head and the shoulder.

11. The electronic assembly according to claim 2, wherein the shell is formed with a solder pad adapted to be soldered to a surface of the circuit board.

12. The electronic assembly according to claim 11, wherein the shell has a first shell wall and a second shell wall positioned opposite to each other in a first direction, the first shell wall and the second shell wall adapted to be at least partially butted against the side walls of the module housing to limit a displacement of the connector module in the first direction.

13. The electronic assembly according to claim 12, wherein:
each of the first shell wall and the second shell wall are adapted to be respectively positioned between one of the side walls of the module housing and the fastener of the fixing assembly; and
a notch adapted to be passed through by the shoulder of the module housing is formed in each of the first shell wall and the second shell wall, respectively.

14. The electronic assembly according to claim 13, wherein at least one elastic arm is formed on at least one of the first shell wall and the second shell wall, and the at least one elastic arm is adapted to be at least partially elastically butted against the side walls of the module housing when the connector module is positioned inside the shell.

15. The electronic assembly according to claim 14, wherein:
the at least one elastic arm includes at least one of a first elastic arm and a second elastic arm;
the first elastic arm extends from a base of a corresponding shell wall in a direction away from the circuit board and is inclined towards inside of the shell, such that at least a free end of the first elastic arm is elastically butted against the side wall of the module housing; and
the second elastic arm extends from a top of a corresponding shell wall in a direction towards the circuit board and is inclined towards inside of the shell, such that at least a portion of the second elastic arm is elastically butted against the side wall of the module housing.

16. The electronic assembly according to claim 15, wherein a free end of the second elastic arm is adapted to press against the socket connector in a direction towards the connector module.

17. The electronic assembly according to claim 16, wherein a protrusion is formed on an inner surface of the free end of the second elastic arm facing the connector module, the protrusion is adapted to press an upper edge of the socket connector in a direction towards the circuit board, thereby positioning the socket connector.

18. The electronic assembly according to claim 17, wherein:
the at least one elastic arm of each of the first shell wall and the second shell wall includes two second elastic arms and one first elastic arm located between the two second elastic arms;
the notch of the first shell wall includes two first notches, and the one first elastic arm and the two second elastic arms of the first shell wall are provided between the two first notches; and
the notch of the second shell wall includes two second notches, each of the second notches is arranged between the first elastic arm and the second elastic arm of the second shell wall.

19. The electronic assembly according to claim 11, wherein the shell is integrally formed by stamping and bending a single metal plate.

20. The electronic assembly according to claim 19, wherein:
two ends of the metal plate are formed with a protrusion and a recess that are complementary, and are embedded and connected with each other to form a third shell wall of the shell; and
solder pads are formed at a base of each of a first shell wall, a second shell wall, and the third shell wall of the shell.
